(19) United States
(12) Patent Application Publication
(10) Pub. No.: US 2019/0025056 A1
(43) Pub. Date: Jan. 24, 2019

(54) ELECTROSTATIC OFFSET CORRECTION

(71) Applicant: InvenSense, Inc., San Jose, CA (US)

(72) Inventors: Kevin Hughes, Sasn Jose, CA (US); Joseph Seeger, Menlo Park, CA (US); Karthik Vijayraghavan, San Jose, CA (US)

(73) Assignee: InvenSense, Inc., San Jose, CA (US)

(21) Appl. No.: 15/657,054

(22) Filed: Jul. 21, 2017

(51) Int. Cl. G01C 19/5712; G01P 15/125; B81B 7/00

(52) U.S. Cl. CPC G01C 19/5712; G01P 15/125; B81B 7/0064; B81B 2201/0242; B81B 2203/0163; B81B 2201/0235; B81B 2203/0181

(57) ABSTRACT

A MEMS sensor has a proof mass, a sense electrode, and a shield. At least a portion of the proof mass and shield may form a capacitor that causes an offset movement of the proof mass. A series of test values may be provided in order to minimize the offset movement or compensate for the offset movement. In some embodiments, the shield voltage may be modified to reduce the offset movement. Residual offsets due to other factors may also be determined and utilized for compensation to reduce an offset error in a sensed signal.

### BACKGROUND

Numerous items such as smart phones, smart watches, tablets, automobiles, aerial drones, appliances, aircraft, exercise aids, and game controllers may utilize motion sensors during their operation. In many applications, various types of motion sensors such as accelerometers and gyroscopes may be analyzed independently or together in order to determine varied information for particular applications. For example, gyroscopes and accelerometers may be used in gaming applications (e.g., smart phones or game controllers) to capture complex movements by a user, drones and other aircraft may determine orientation based on gyroscope measurements (e.g., roll, pitch, and yaw), and vehicles may utilize measurements for determining direction (e.g., for dead reckoning) and safety (e.g., to recognizing skid or roll-over conditions).

Motion sensors such as accelerometers and gyroscopes may be manufactured as microelectromechanical (MEMS) sensors that are fabricated using semiconductor manufacturing techniques. A MEMS sensor may include movable proof masses that can respond to forces such as linear acceleration (e.g., for MEMS accelerometers) and angular velocity (e.g., for MEMS gyroscopes). The operation of these forces on the movable proof masses may be measured based on the movement of the proof masses in response to the forces. In some implementations, this movement is measured based on distance between parallel surfaces of the movable proof masses and sense electrodes, which form capacitors for sensing the movement.

The capacitance is based on distance and the voltages of the proof mass and sense electrode. However, other components of the system such as a shield layer on a substrate or cap may also have a voltage and may be located in positions (e.g., parallel) relative to the proof mass such that these other components also form a capacitor with the proof mass. Based on the relative voltage of the movable proof mass and fixed shield, this capacitor may result in a force on the proof mass and a resulting displacement of the proof mass. This displacement of the proof mass occurs is in the absence of any inertial and results in an error when attempting to measure a sensed motion of the proof mass (e.g., as a result of linear acceleration or angular velocity).

### SUMMARY OF THE INVENTION

In an exemplary embodiment of the present disclosure, a microelectromechanical (MEMS) sensor may comprise a proof mass having a plurality of planar surfaces and having a proof mass voltage. The MEMS sensor may also comprise a sense electrode having one or more planar surfaces, wherein at least one of the one or more planar surfaces of the sense electrode is located in parallel to at least one of the planar surfaces of the proof mass, wherein the sense electrode has a sense electrode voltage, and wherein the sense electrode and the proof mass form a sense capacitor. The MEMS sensor may also comprise a shield located on one or more planar surfaces of the microelectromechanical sensor, wherein at least a portion of the shield is located in parallel to at least one of the planar surfaces of the proof mass, and wherein the shield has a modifiable shield voltage. The MEMS sensor may also comprise processing circuitry coupled to the proof mass, the sense electrode, and the shield, wherein the processing circuitry provides a plurality of test voltages for the modifiable shield voltage, measures an offset value at each of the test voltages, and sets the modifiable shield voltage to an operating shield voltage based on the plurality of measured offset values, and wherein the movement of the proof mass relative to the sense electrode is sensed based on changes in the value of the sense capacitor.

In an exemplary embodiment of the present disclosure, a method for operating a microelectromechanical (MEMS) sensor may comprise providing, to a shield of the MEMS sensor, a plurality of test voltages, determining, based on measured movement of a proof mass of the MEMS sensor, an offset value associated with each of the plurality of test voltages, identifying, based on the measured movements of the proof mass, a voltage-induced sensor offset associated with an operating voltage of the shield, and identifying, based on the measured movements of the proof mass, a mechanical sensor offset for the proof mass. The method may further comprise measuring, based on a capacitor formed by the proof mass and a sense electrode of the MEMS sensor, a measured value for the sensor, and correcting the measured value based on the voltage-induced sensor offset and the mechanical sensor offset.

In an exemplary embodiment of the present disclosure, a microelectromechanical (MEMS) sensor may comprise a proof mass having a plurality of planar surfaces and having a proof mass voltage. The MEMS sensor may further comprise a sense electrode having one or more planar surfaces, wherein at least one of the one or more planar surfaces of the sense electrode is located in parallel to at least one of the planar surfaces of the proof mass, wherein the sense electrode has a sense electrode voltage, and wherein the sense electrode and the proof mass form a sense capacitor. The MEMS sensor may further comprise a shield located on one or more planar surfaces of the microelectromechanical sensor, wherein at least a portion of the shield is located in parallel to at least one of the planar surfaces of the proof mass. The MEMS sensor may further comprise processing circuitry coupled to the proof mass, the sense electrode, and the shield, wherein the processing circuitry provides a plurality of test voltages to one or more of the proof mass or the shield, measures an offset value at each of the test voltages, identifies a minimum offset value based on the measured offset values, determines a voltage-induced sensor offset based on the minimum offset value and an operating voltage of the shield, determines a mechanical sensor offset based on the minimum offset value, and modifies a sensed signal from the sense capacitor based on the voltage-induced sensor offset and the mechanical sensor offset.

### BRIEF DESCRIPTION OF THE DRAWINGS

The above and other features of the present disclosure, its nature and various advantages will be more apparent upon consideration of the following detailed description, taken in conjunction with the accompanying drawings in which:

FIG. 1 shows an illustrative motion sensing system in accordance with an embodiment of the present disclosure;

FIG. 2A shows a section view of an illustrative portion of a microelectromechanical (MEMS) inertial sensor including sense electrodes and a shield in accordance with some embodiments of the present disclosure;

FIG. 2B shows a section view of an illustrative portion of the MEMS inertial sensor of FIG. 2A experiencing out of plane sense in response to an inertial force in accordance with some embodiments of the present disclosure;

FIG. 3A shows a top view of an illustrative MEMS system for sensing linear acceleration having sense electrodes and a shield located on a substrate in accordance with some embodiments of the present disclosure;

FIG. 3B shows a side section view of an illustrative MEMS system having sense electrodes and a shield located on a substrate for sensing linear acceleration in accordance with some embodiments of the present disclosure;

FIG. 4 shows an illustrative system for sensing angular velocity in accordance with some embodiments of the present disclosure;

FIG. 5A shows an exemplary plot depicting a sensor offset due to mechanical sensor offset and voltage-induced sensor offset in accordance with some embodiments of the present disclosure;

FIG. 5B shows an exemplary plot depicting a sensor offset after correction of mechanical sensor offset and voltage-induced sensor offset in accordance with some embodiments of the present disclosure;

FIG. 6 shows an exemplary plot depicting a plot of operational offset change of a sensor in accordance with some embodiments of the present disclosure;

FIG. 7 depicts a block diagram of open loop correction in accordance with some embodiments of the present disclosure;

FIG. 8 depicts a block diagram of closed loop correction in accordance with some embodiments of the present disclosure;

FIG. 9 depicts steps for an initial offset correction in accordance with some embodiments of the present disclosure; and

FIG. 10 depicts steps for active offset correction in accordance with some embodiments of the present disclosure.

### DETAILED DESCRIPTION

A MEMS device is constructed of a number of layers such as a CMOS layer, a MEMS device layer, and a cap layer. The MEMS device layer includes a movable proof mass that is suspended from the MEMS device layer by components such as springs masses, and lever arms. At least one sense electrode is located parallel to a surface of the proof mass (e.g., on a substrate such as the top of the CMOS layer, or on a post that extends into the MEMS plane) for use in sensing a position or orientation of the proof mass. Each of the proof mass and sense electrode are conductive and have respective voltages. At least a portion of the proof mass includes a planar surface that is located opposite and parallel to the sense electrode to form a capacitor. The proof mass is suspended in a manner such that its primary movement relative the sense electrode is due to an inertial force that is desired to be measured, such as linear acceleration along the axis along which the proof mass is displaced, or a Coriolis force along the sense axis due to an angular velocity that is perpendicular to the sense axis. Processing circuitry measures the capacitance based on signals received from the sense electrode or proof mass, to determine a value indicative of the movement of the electrode. Based on a change in the capacitance and scaling factors, the processing circuitry determines a motion parameter indicative of motion (e.g., linear acceleration or angular velocity) of the MEMS device. As an example, the MEMS device may form an accelerometer, gyroscope, pressure sensor, or other type of motion sensor.

In an embodiment, one or more other portions or components of the MEMS device may have one or more voltages that are independent from either of the sense electrode and the proof mass. For example, a portion of additional electrodes substrate, cap, CMOS layer, MEMS layer, anchor, frame, or other similar component may have such a voltage, and may also be located at a position relative to the proof mass such that a capacitor is formed with at least a portion of the proof mass. Although it will be understood that the present disclosure may apply to a variety of components located at a variety of locations relative to the proof mass, in an exemplary embodiment described herein an electrode shield is located on a substrate surface (e.g., of a CMOS layer) that is parallel to a planar surface of the proof mass and that surrounds the sense electrodes. Because the shield is located on a fixed surface while the proof mass is movable, the capacitor formed by the shield and the proof mass may exert a force on the proof mass, which may cause the proof mass to move relative to the shield and the sense electrode. As a result of this voltage-induced sensor offset, an error is induced in the measured response to an inertial force along the sense axis.

The voltage of the shield may be modified which may also result in a change in the voltage-induced sensor offset. In an embodiment, this shield voltage may be set to an initial value based on an expected voltage at which the voltage-induced sensor offset is at a minimum. The shield voltage may then be varied in order to determine whether the initial offset is correct, and if not, to modify the initial offset. Such testing may be performed in a variety of manners, such as by performing a sweep of possible shield voltages or iterative searching based on measured absolute and/or derivative (slope) values for the offset. In this manner, a shield voltage that is associated with a minimum offset available value (e.g., based on applied shield voltage resolution) may be determined. In some instances, a sensor offset may exist even when the voltage-induced sensor offset is minimized. This mechanical sensor offset may be a result of mechanical factors (e.g., manufacturing tolerances, fabrication imperfections, stress-induced deformation), other system voltages that are not adjustable, or other similar factors such as electrical impacts of circuits within signal paths (e.g., ADC offset or differential capacitance mismatch within an output path).

Once the shield voltage that is associated with the minimum voltage-induced sensor offset is determined, processing may be performed in order improve the accuracy of the MEMS sensor. Compensation may be performed based on the determined mechanical sensor offset in order to remove the impact of the mechanical sensor offset from the signals that are sensed during normal operations. In some embodiments, the initial shield voltage may be retained but compensation may be performed based on the voltage-induced sensor offset at the initial voltage. In some embodiments, the shield voltage may be modified in order to remove some or all of the voltage-induced sensor offset. If the shield voltage is set to a revised voltage that corresponds to the minimum voltage for voltage-induced sensor offset, then it may be unnecessary to perform compensation for voltage-induced sensor offset. If another revised shield voltage is selected, compensation may be performed based on the voltage-induced sensor offset that is associated with the selected revised voltage.

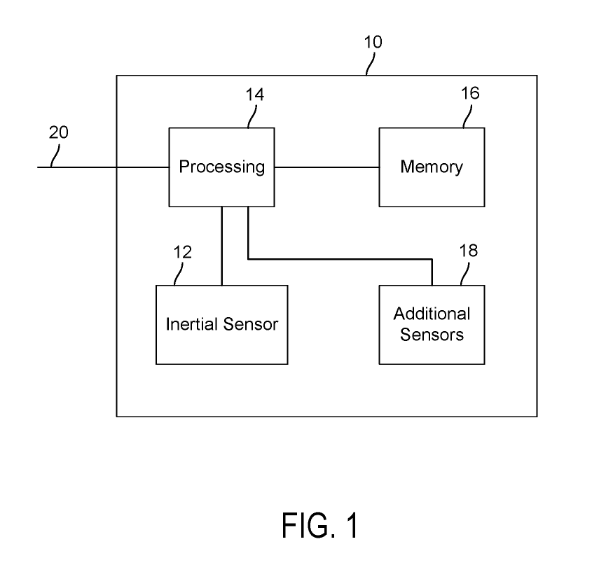

FIG. 1 depicts an exemplary motion sensing system 10 in accordance with some embodiments of the present disclosure. Although particular components are depicted in FIG. 1, it will be understood that other suitable combinations of sensors, processing components, memory, and other circuitry may be utilized as necessary for different applications and systems. In an embodiment as described herein, the motion sensing system may include at least a MEMS inertial sensor 12 (e.g., a single or multi-axis accelerometer, a single or multi-axis gyroscope, or combination thereof) and supporting circuitry, such as processing circuitry 14 and memory 16. In some embodiments, one or more additional sensors 18 (e.g., additional MEMS gyroscopes, MEMS accelerometers, MEMS microphones, MEMS pressure sensors, and a compass) may be included within the motion processing system 10 to provide an integrated motion processing unit (“MPU”) (e.g., including 3 axes of MEMS gyroscope sensing, 3 axes of MEMS accelerometer sensing, microphone, pressure sensor, and compass).

Processing circuitry 14 may include one or more components providing necessary processing based on the requirements of the motion processing system 10. In some embodiments, processing circuitry 14 may include hardware control logic that may be integrated within a chip of a sensor (e.g., on a substrate or cap of an inertial sensor 12 or other sensor 18, or on an adjacent portion of a chip to the inertial sensor 12 or other sensor 18) to control the operation of the inertial sensor 12 or other sensor 18 and perform aspects of processing for the inertial sensor 12 or other sensor 18. In some embodiments, the inertial sensor 12 and other sensors 18 may include one or more registers that allow aspects of the operation of hardware control logic to be modified (e.g., by modifying a value of a register). In some embodiments, processing circuitry 14 may also include a processor such as a microprocessor that executes software instructions, e.g., that are stored in memory 16. The microprocessor may control the operation of the inertial sensor 12 by interacting with the hardware control logic, and process signals received from inertial sensor 12. The microprocessor may interact with other sensors in a similar manner.

In an embodiment, processing circuitry 14 may perform steps to eliminate and/or compensate for voltage-induced sensor offset and mechanical sensor offset as described herein of any of the sensor 12 or sensors 18. At one or more stages of the life cycle of any such sensor (e.g., manufacturing, final inspection, initial startup in the field, upon each application of power, periodically, after extended periods without experiencing an inertial force, or other suitable times), the processing circuitry may perform testing of the sensor offsets by modifying the shield voltage (or in some embodiments, other voltages or multiple voltages) while measuring the response of the proof mass to the modified shield voltage. Based on the results, the minimum shield voltage that corresponds to a minimum proof mass response may be associated with a minimum (e.g., substantially zero) voltage-induced sensor offset. In some embodiments, a mechanical sensor offset may also be determined, based on any remaining offset at the minimum shield voltage. The processing circuitry may compensate for the mechanical sensor offset, and in some embodiments, compensate for the voltage-induced sensor offset at a voltage other than the minimum shield voltage. In some embodiments, the operational shield voltage may be modified (e.g., to the minimum shield voltage) to eliminate or reduce the voltage-induced sensor offset.

Although in some embodiments (not depicted in FIG. 1), the inertial sensor 12 or other sensors 18 may communicate directly with external circuitry (e.g., via a serial bus or direct connection to sensor outputs and control inputs), in an embodiment the processing circuitry 14 may process data received from the inertial sensor 12 and other sensors 18 and communicate with external components via a communication interface 20 (e.g., a SPI or I2C bus, or in automotive applications, a controller area network (CAN) or Local Interconnect Network (LIN) bus). The processing circuitry 14 may convert signals received from the inertial sensor 12 and other sensors 18 into appropriate measurement units (e.g., based on settings provided by other computing units communicating over the communication bus 20) and perform more complex processing to determine measurements such as orientation or Euler angles, and in some embodiments, to determine from sensor data whether a particular activity (e.g., walking, running, braking, skidding, rolling, etc.) is taking place and quantify or otherwise analyze that activity.

In some embodiments, certain types of information may be determined based on data from multiple inertial sensors 12 and sensors 18, in a process that may be referred to as sensor fusion. By combining information from a variety of sensors it may be possible to accurately determine information that is useful in a variety of applications, such as image stabilization, navigation systems, automotive controls and safety, dead reckoning, remote control and gaming devices, activity sensors, 3-dimensional cameras, industrial automation, and numerous other applications.

An exemplary MEMS inertial sensor (e.g., inertial sensor 12) may include one or more movable proof masses that are configured in a manner that permits the MEMS inertial sensor (e.g., a MEMS accelerometer or MEMS gyroscope) to measure a desired force (e.g., linear acceleration or angular velocity) along an axis. In some embodiments, the one or more movable proof masses may be suspended from anchoring points, which may refer to any portion of the MEMS sensor which is fixed, such as an anchor that extends from a layer (e.g., a CMOS layer) that is parallel to the MEMS layer of the device, a frame of the MEMS layer of the device, or any other suitable portion of the MEMS device that is fixed relative to the movable proof masses. The proof masses may be arranged in a manner such that they move in response to measured force. The movement of the proof masses relative to a fixed surface (e.g., a fixed sense electrode extending in to the MEMS layer or located parallel to the movable mass on the substrate) in response to the measured force is measured and scaled to determine the desired inertial parameter.

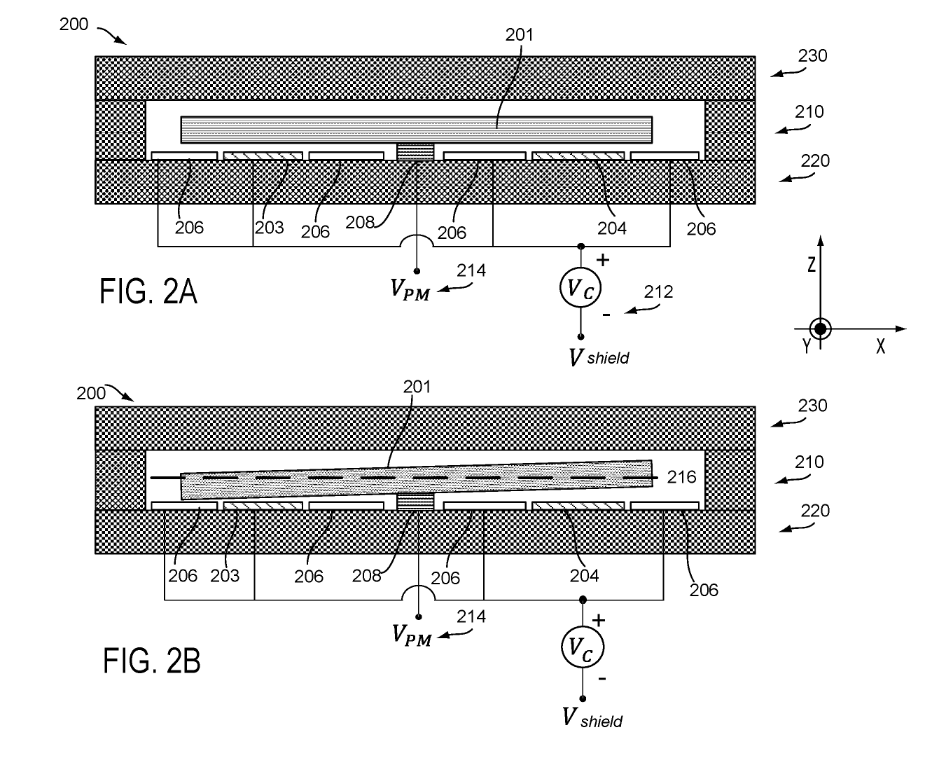

FIG. 2A depicts a section view of a portion of an illustrative inertial sensor 200 that is configured to sense an external force (e.g., a linear acceleration along an axis or an angular velocity about an axis) based on out-of-plane movement of a proof mass in accordance with some embodiments of the present disclosure. Although particular components are depicted and configured in a particular manner in FIG. 2A, it will be understood that a motion sensing inertial sensor 200 may include other suitable components and configurations. The section view of FIG. 2A depicts a limited subset of components of a MEMS inertial sensor, which generally include a spring-mass system within a MEMS layer including various components such as springs, proof masses, coupling masses, drive masses, drive electrodes and combs, sense electrodes and combs, lever arms, couplings, and other suitable electromechanical components that are manufactured using semiconductor manufacturing techniques. The set of components depicted in FIG. 2A provide a configuration for out-of-plane capacitive sensing by an inertial sensor. An exemplary MEMS accelerometer may experience a force along the z-axis (i.e., out of the x-y MEMS device plane) in response to a linear acceleration in a direction along that axis. An exemplary gyroscope may experience a force along the z-axis (i.e., out of the x-y MEMS device plane) in response to a Coriolis force along the z-axis as a result of an angular velocity about an axis that is perpendicular to the z-axis and a drive axis of the MEMS gyroscope.

In the embodiment of FIG. 2A, the inertial sensor 200 is constructed of a plurality of bonded semiconductor layers. Although a MEMS device may be constructed in a variety of manners, in an embodiment, the MEMS device may include a substrate 220, a MEMS layer 210, and a cap layer 230 that are bonded together at certain points to form a hermetically sealed package. The substrate 220 may include CMOS circuitry and form a CMOS layer of the MEMS device, though the CMOS circuitry may reside in other portions of the device, such as cap layer 230, or in some embodiments, external to the MEMS die. An exemplary MEMS layer may be produced using semiconductor manufacturing techniques to construct micromechanical components for use in applications such as MEMS sensors (e.g., accelerometers, gyroscopes, pressure sensors, microphones, etc.). An exemplary CMOS layer may provide for the integration of electrical components and devices within the CMOS layer, and may also provide for interconnections between those components. In some embodiments, the components of the MEMS layer 210 may be conductive, and interconnections between components of the MEMS layer and the CMOS layer may be provided. As an example, circuitry within the CMOS layer may electrically couple electrical components (e.g., electrodes or movable proof masses) of the MEMS layer to processing circuitry 14 or other electrical components.

In an exemplary embodiment, the MEMS layer 210 may include at least one anchoring point 208 and at least one movable proof mass 201 that is attached to the anchoring point 208 and suspended above the substrate 220. The anchoring point 208 may be fixedly attached (e.g., bonded) to and extend from a planar surface of the substrate 220. The anchoring point 208 and the movable proof mass 201 may be composed of conductive material, and the movable proof mass 201 may be arranged to pivot about the anchoring point 208 such that one end of the proof mass 201 tilts up while the other end tilts down in response to a sensed inertial force. Thus, when one side of the proof mass surface moves away from the substrate 220 the other side of the proof mass surface on the opposite end moves toward the substrate 220. Although not depicted in FIG. 2A, springs and couplings may be connected to the proof mass, in-plane anchors, and other components within the MEMS layer in a manner that restricts movement of the proof mass to desired movements in response to measured inertial forces, such as along an axis of a sensed linear acceleration in the case of a MEMS accelerometer or along a Coriolis axis (and in some embodiments, a drive axis) for a MEMS gyroscope.

The proof mass 201 may define a plurality of planar surfaces, including an upper planar surface (top of proof mass 201, in the x/y plane) and a lower planar surface (bottom of proof mass 201, in the x/y plane). Although in different embodiments a proof mass may have a plurality of different shapes within the MEMS device plane, in the exemplary embodiment of FIG. 2A, the proof mass 201 includes at least a left-side planar surface (left side of proof mass 201, in the y/z plane) and a right-side planar surface (right side of proof mass 201, in the y/z plane). A voltage may be applied to the proof mass, for example, by a proof mass voltage source 214. Although proof mass voltage source 214 is depicted within substrate 220, it will be understood that the proof mass voltage may be applied in a variety of manners. In some embodiments, the voltage that the proof mass voltage source 214 provides to the proof mass 201 may be modifiable, e.g., during manufacturing or in operation. Although the present disclosure generally describes modifying other voltages of the MEMS sensor (e.g., a shield voltage applied by shield voltage source 212 to shield 209), in some embodiments adjustments may be made to the proof mass voltage (and in further variations, to corresponding sense electrodes) in order to reduce the voltage-induced sensor offset.

The inertial sensor 200 may also comprise at least one sense electrode that, in conjunction with the proof mass 201, forms a capacitor. The exemplary embodiment of FIG. 2A shows two sense electrodes 203 and 204 positioned on a planar surface of the substrate 220 on opposite sides of the anchoring point 208, but other numbers and arrangements of sense electrodes are possible in other embodiments. An electrode shield 209 may also be formed on the substrate (e.g., surrounding the sense electrodes), and in some embodiments may be of a same or similar material as the sense electrodes. In an embodiment, the shield 209 may have a voltage that is provided from a shield voltage source 212 that is independent of the proof mass 201 and electrodes 203 and 204. In some embodiments, the shield voltage provided by the shield voltage source may be adjustable. The exemplary shield 209 of FIG. 2 is located in a x-y plane that is parallel to the lower x-y plane of proof mass 201, and the shield 209 and proof mass form a capacitor.

Each sense electrode 203 and 204 faces an opposite portion of the lower planar surface of the proof mass 201 that is suspended above the substrate 220. Using these sense electrodes 203 and 204, the position of the proof mass 201 is capacitively sensed. In this regard, the value of the capacitance between sense electrode 203 and the proof mass 201 changes based upon the distance between the upper planar surface of sense electrode 203 and the lower planar surface of proof mass 201. The capacitance between sense electrode 204 and the proof mass 201 changes based upon the distance between the upper planar surface of sense electrode 204 and the lower planar surface of proof mass 201.

The capacitance formed by each capacitor may be sensed, and the capacitance signals may be processed (e.g., by filtering, amplification, scaling, etc.) to determine information about the sensed inertial force. In an exemplary embodiment, the memory 16 (FIG. 1) stores data that is used by the processing circuitry 14 in order to convert the sensed voltage into measurements of motion, e.g., linear acceleration or angular velocity. This data may be calibrated during manufacturing or at other times such that a certain movement by the proof mass 201 corresponds to a certain change in the measured motion parameter. To the extent that the default position (i.e., in the absence of a force along the sense axis) of the lower surface of the proof mass is not in the x-y plane (e.g., as a result of voltage-induced sensor offset and/or a mechanical sensor offset), the sensed movement of the proof mass 201 in response to a force along the sense axis will be incorrect. As is depicted in FIG. 2A (i.e., in the absence of a sensed inertial force, the proof mass 201 is slightly offset as a result of the sensor offsets.

FIG. 2B depicts a section view of a portion of the illustrative inertial sensor 200 sensing an inertial force that causes movement of the proof mass along the sense axis in accordance with some embodiments of the present disclosure. As is depicted in FIG. 2B, a portion of the proof mass 201 moves towards to the sense electrode 203 while a portion of the proof mass 201 moves away from sense electrode 204. Reference line 216 depicts where the lower plane of proof mass 201 would be located in the absence of a sensor offset. Thus, as a result of the sensor offset the sense electrodes sense an acceleration that is proportionally incorrect based on the relative size of the offset vis-à-vis the movement in response to the sensed inertial force.

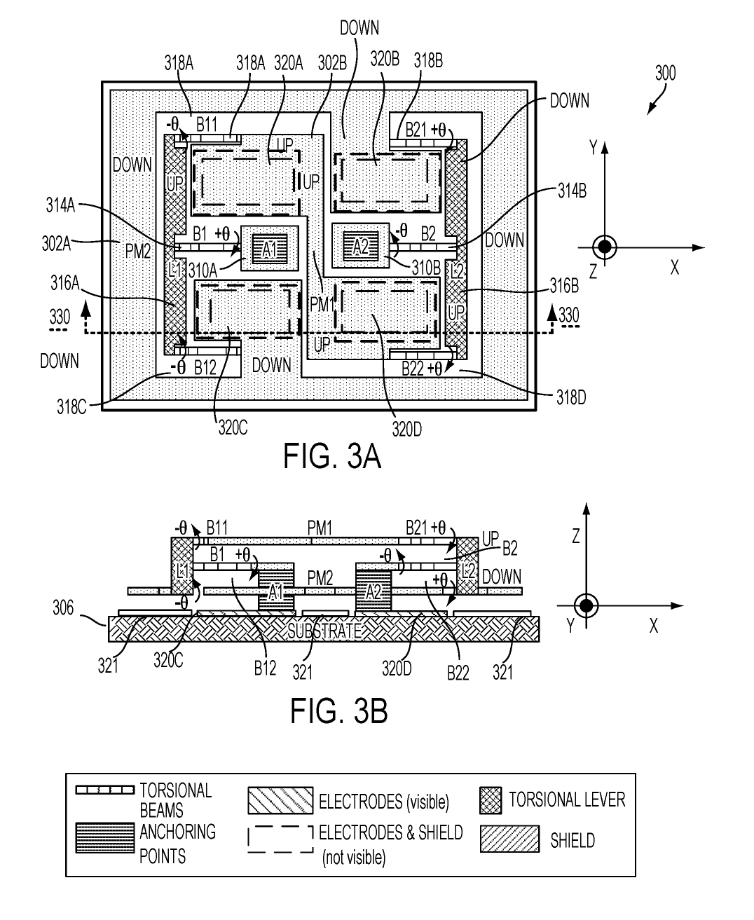

FIG. 3A depicts a top view of an exemplary MEMS accelerometer 300 for that responds to a linear acceleration along a z-axis in accordance with some embodiments of the present disclosure. The accelerometer 300 comprises two proof masses PM1 302B and PM2 302A that respond to a linear acceleration along the z-axis by moving in anti-phase direction normal to an upper planar surface of sense electrodes 320A-320D, which are located on a surface of a substrate 306. An electrode shield 321 may also be formed on the substrate (e.g., surrounding the sense electrodes), and in some embodiments may be of a same or similar material as the sense electrode. The anti-phase movement is constrained by a flexible coupling between the two proof masses PM1 302B and PM2 302A and the substrate 306. The flexible coupling comprises two separated anchoring points A1 310A and A2 310B, two central torsional springs B1 314A and B2 314B, two rotational levers L1 316A and L2 316B and four external torsional springs B11 318A, B21 318B, B12 318C and B22 318D. The motion of the accelerometer 300 is measured based on the out-of-plane movement of the proof masses relative to capacitive sense electrodes 320A-320D.

FIG. 3B shows a side section view of the illustrative MEMS system for sensing linear acceleration in accordance with some embodiments of the present disclosure, viewed from section line 330 of FIG. 3A. FIGS. 3A and 3B depict proof mass PM1 302B as moving away from the underlying substrate in the “UP” direction and proof mass PM2 302A moving towards the underlying substrate in the “DOWN” direction. Sense electrodes 320A (not depicted in FIG. 3B), 320B (not depicted in FIG. 3B), 320C, and 320D are located on the substrate, with 320A and 320B located behind anchors A1 and A2 and sense electrode 320C and 320D located in front of anchors A1 and A2. Each of the sense electrodes is connected to a sense path (e.g., within CMOS circuitry of the substrate) that includes analog and digital circuitry such as a C-to-V converters, amplifiers, comparators, filters, and scaling to determine acceleration based on the capacitances sensed by the sense electrodes. Shield 321 is also located on substrate 306, surrounding the sense electrodes 320A-320D and in a plane that is parallel to the proof masses 302A and 302B. To the extent that an accelerometer offset is imparted on the proof masses, the sense electrodes may sense an acceleration that is proportionally incorrect based on the relative size of the offset vis-à-vis the movement in response to the sensed inertial force.

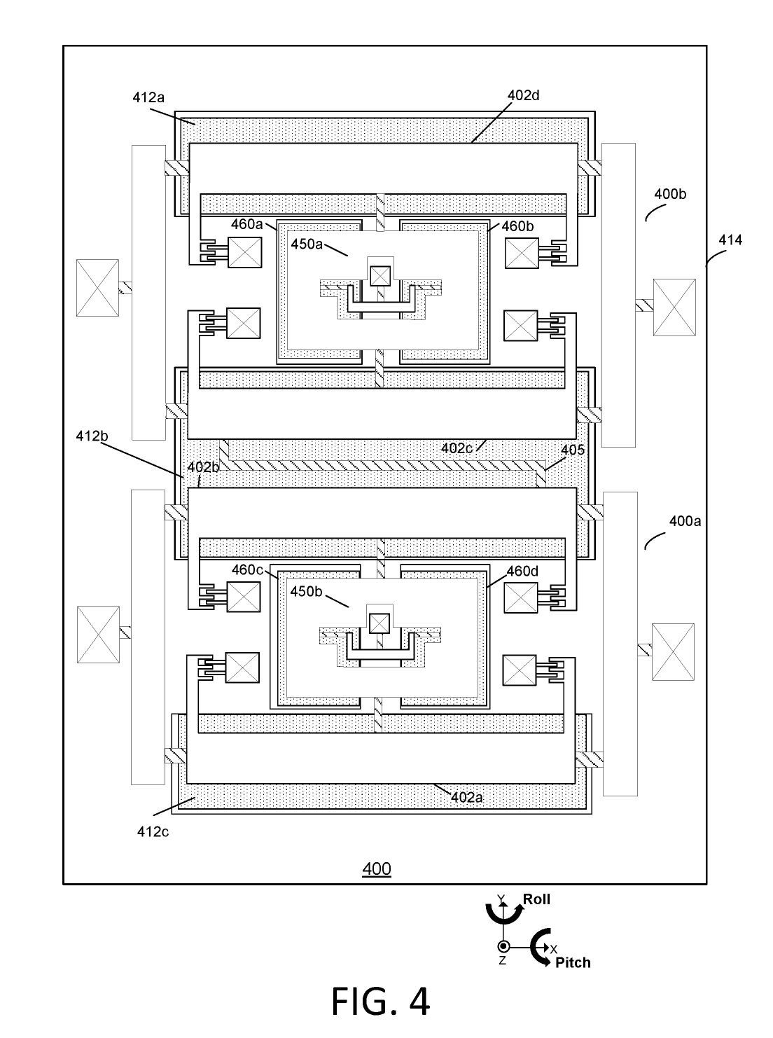

FIG. 4 depicts an illustrative MEMS gyroscope with voltage sensing of multiple movable masses relative to sense electrodes in accordance with some embodiments of the present disclosure. The gyroscope design of FIG. 4 is provided for purposes of illustration and not limitation. It will be understood that the principles of the present disclosure may apply to any suitable MEMS device (e.g., MEMS accelerometers, gyroscopes, pressure sensors, microphones, etc.) and to any suitable configuration of such devices. The exemplary embodiment of FIG. 4 illustrates an embodiment of a dual-axis gyroscope comprising a balanced guided mass system 400. The guided mass system 400 comprises two guided mass systems 400a and 400b coupled together by coupling spring 405.

The symmetric guided mass system 400a rotates out-of-plane about a first roll-sense axis. The symmetric guided mass system 400b rotates out-of-plane about a second roll-sense axis in-plane and parallel to the first roll-sense axis. In an embodiment, pitch proof-masses 450a and 450b are each flexibly connected to their respective four roll proof-masses 402a-402d via springs. The springs are torsionally compliant such that pitch proof-mass 450a can rotate out-of-plane about a first pitch sense axis in the y-direction relative to sense electrodes 460a and 460b, and such that pitch proof-mass 450b can rotate out-of-plane about a second pitch sense axis in the y-direction relative to sense electrodes 460c-460d.

Angular velocity about the pitch-input axis in the x-direction will cause Coriolis forces to act on the pitch proof-masses 450a and 450b about the first and second pitch-sense axes respectively. The Coriolis forces cause the pitch proof masses 450a and 450b to rotate anti-phase out-of-plane about the first and the second pitch-sense axes. The amplitudes of the rotations of the pitch proof-masses 450a and 450b about the first and the second pitch-sense axes are proportional to the angular velocity about the pitch-input axis.

In an embodiment, sense electrodes 460a-460d located on the substrate and under the pitch proof masses 450a and 450b are used to detect the anti-phase rotations about the first and the second pitch-sense axes. An electrode shield 414 may also be formed on the substrate (e.g., surrounding the sense electrodes), and in some embodiments may be of a same or similar material as the sense electrode. Externally applied angular acceleration about the roll-input axis will generate inertial torques in-phase on the pitch proof masses 450a and 450b causing them to rotate in-phase about the first and the second pitch-sense axes. To the extent that a gyroscope offset is imparted on the proof masses, the sense electrodes may sense an acceleration that is proportionally incorrect based on the relative size of the offset vis-à-vis the movement in response to the sensed inertial force.

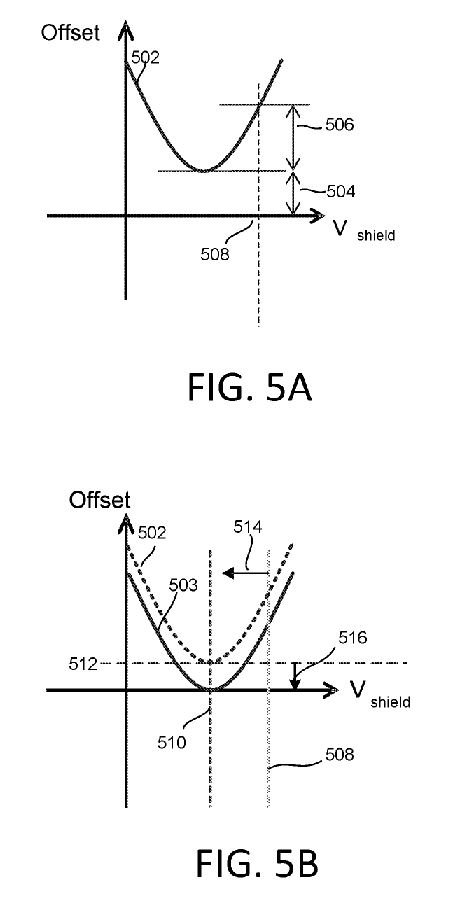

FIG. 5A shows an exemplary plot depicting a sensor offset due to mechanical sensor offset and voltage-induced sensor offset in accordance with some embodiments of the present disclosure. The abscissa of FIG. 5A represents the voltage of a component of a MEMS sensor for which a sensor offset is being analyzed, and in an exemplary embodiment may be a shield of an inertial sensor such as a MEMS accelerometer or gyroscope (e.g., a suitable voltage range for an appropriate sensor, such as 0 to 1.5V for an exemplary accelerometer). The shield may be located relative to a component such as a proof mass, such as on a substrate (e.g., surrounding one or more sense electrodes) that is parallel to a surface of the proof mass. The ordinate of FIG. 5A represents an offset that is induced on the proof mass by different shield voltages, for example, by holding other system voltages constant while performing such analysis and determining a measure of movement (e.g., as measured by a sensed capacitance at a sense electrode) of the proof mass due to the shield voltage.

Initial voltage 508 corresponds to an initial shield voltage, which may correspond to an arbitrary value or may be a selected value (e.g., a standard initial value provided during manufacturing or an updated value applied during sensor operation). Offset curve 502 represents an offset that is experienced by the proof mass in response to certain shield voltages. In exemplary embodiments, an offset curve or a portion thereof may be established by applying a number of shield voltages and determining offset responses to those applied shield voltages. A variety of search techniques may be applied, for example, based on known characteristics of an offset curve. By testing shield voltages that result in an increase or decrease in offset value, a change in slope (i.e., derivative) of offset values, or other suitable measurements, an offset curve 502 may be at least partially interpolated.

In some embodiments it may be possible to determine the offset curve 502 without modifying the shield voltage (e.g., for a sensor that does not have a variable shield voltage) or to use other information to assist in generating the offset curve 502 (e.g., with a shield voltage having limited resolution. Other voltages such as the proof mass voltage may be modified (e.g., to change the voltage difference between the shield voltage and the proof mass) or forces may be applied to the proof mass (e.g., to determine the response to particular forces, which may be based at least in part on the capacitance formed between the proof mass and the shield.

By establishing the offset curve 502, it may be possible to determine a mechanical sensor offset 504 and a voltage-induced sensor offset 506. A mechanical sensor offset 504 may be an offset that is not attributable to the component under analysis (e.g., the shield). Other components may create independent voltage-induced sensor offset s of their own (e.g., additional voltage-induced sensor offsets), and an offset error may be the result of manufacturing tolerances or changes in sensor function over time (e.g., mechanical sensor offsets). In some embodiments, it may be possible to optimize the voltage of multiple components, thereby reducing at least the non-mechanical portion of any mechanical sensor offset.

As is depicted in FIG. 5A, the mechanical sensor offset 504 corresponds to the minimum offset of the offset curve 502 (e.g., slope=0), which may correspond to the shield voltage at which the voltage-induced sensor offset caused by the shield is optimized. Any remaining offset may thus be the result of mechanical sensor offset 504. FIG. 5B also depicts a voltage-induced sensor offset 506, which corresponds to the additional offset that is experienced by the proof mass when the shield voltage is at the initial voltage 508, as compared to the shield voltage that corresponds to the minimum offset of the offset curve 502.

FIG. 5B shows an exemplary plot depicting a sensor offset after correction of mechanical sensor offset and voltage-induced sensor offset in accordance with some embodiments of the present disclosure. As is described herein, offset correction may be performed in a variety of manners, including by modifying the shield voltage (e.g., to reduce the voltage-induced sensor offset), compensating for the voltage-induced sensor offset (e.g., by modifying scaling factors and/or compensation values of components and/or processing operations), compensating for the mechanical sensor offset (e.g., by modifying scaling factors and/or compensation values of components and/or processing operations), changing voltages of other components (e.g., to reduce a non-mechanical portion of the of mechanical sensor offset), modifying sensor operation (e.g., to change the mechanical portion of the mechanical sensor offset such as by utilizing a tilt-cancelling electrode), temperature compensation, or a combination thereof. In this manner, offset may be performed by changing the operation of the sensor, performing compensation on output signals based on known offsets, or a combination thereof.

In the exemplary embodiment of FIG. 5B, voltage-induced sensor offset correction 514 shifts the effective shield voltage from the initial voltage 508 to the minimum offset voltage 510. The effective shield voltage may be shifted by modifying the shield voltage, performing compensation for the voltage-induced sensor offset at a particular shield voltage, or a combination thereof. This change in the effective shield voltage to the minimum offset voltage 510 results in a remaining offset that corresponds to mechanical sensor offset 516, as is depicted by the difference between the offset 512 at the minimum offset voltage (e.g., as depicted by original offset curve 502) and a zero offset. Offset correction may then be performed for the mechanical sensor offset 516 as described herein, for example, by performing compensation or modifying other aspects of sensor operation that may be reflected in the mechanical sensor offset 516. The result of offset correction may be a resulting offset curve 503, with a minimum offset of zero or approximately zero at the minimum offset voltage.

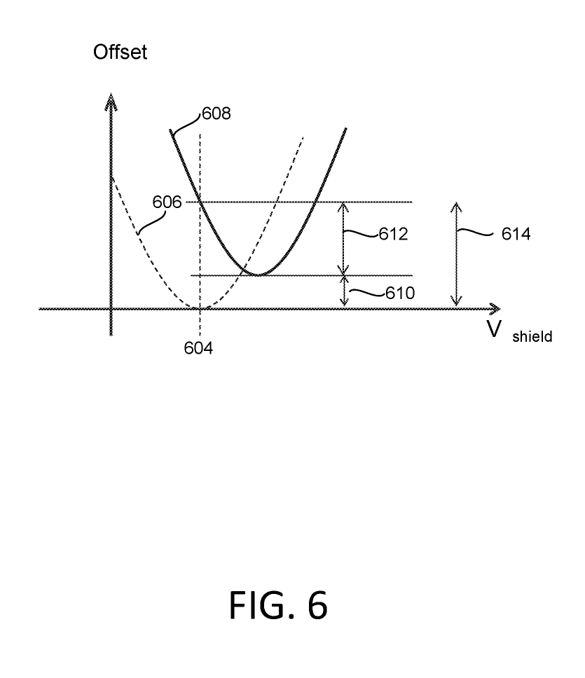

FIG. 6 shows an exemplary plot depicting a plot of operational offset change of a sensor in accordance with some embodiments of the present disclosure. FIG. 6 depicts an initial compensation offset curve 606, which may be determined at a suitable time during manufacturing and/or the operational lifetime of the sensor. In the exemplary embodiment of FIG. 6, an operational shield voltage 604 corresponds to the minimum offset of the offset curve 606, while a mechanical sensor offset was initially removed from offset curve 606 through offset correction. Sensors may have an extensive operational life and may be regularly subjected to stresses such as shocks and extreme environmental conditions. These stresses may result in changes to the physical or electrical characteristics of the sensor over time, which may result in a shift in the offset curve over time.

Offset curve 608 depicts an exemplary shifted offset curve 608. Shifts in the offset curve may result in changes to the mechanical sensor offset, changes in the shape of the offset curve, and changes in the voltage at which the minimum offset voltage of the offset curve occurs. Offset curve 608 may have experienced an increase in the mechanical sensor offset (e.g., in addition to any compensation originally performed for offset curve 606), as is depicted by mechanical sensor offset 610. The minimum offset of the offset curve 608 has also shifted from the minimum offset of offset curve 606, such that the minimum offset of offset curve 608 occurs at a higher shield voltage than operational shield voltage 604. If the shield voltage of the exemplary sensor of FIG. 6 remains at operational voltage 604, the sensor will have a voltage-induced sensor offset 614, which when combined with the mechanical sensor offset 610 results in a total offset change 614. Accordingly, it may be necessary to further correct for the new voltage-induced sensor offset 612 and mechanical sensor offset 610 to ensure continued accuracy in the operation of the sensor of FIG. 6.

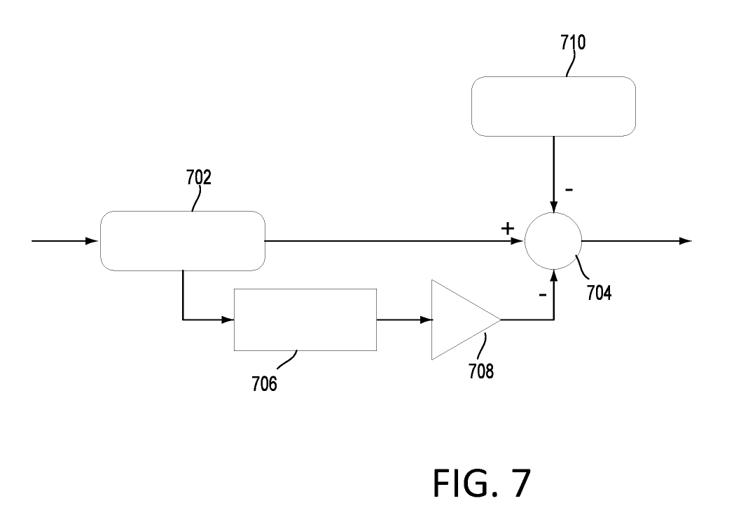

FIG. 7 depicts a block diagram of open loop correction in accordance with some embodiments of the present disclosure. In an exemplary embodiment of open loop correction, correction may be performed by performing compensation on measured values from the sensor. It will be understood that additional blocks may be added to or removed from FIG. 7, and that the function or sequence of the blocks may be modified in a variety of suitable manners.

At block 702, sensing may be performed for the sensor (e.g., an inertial sensor such as a MEMS gyroscope or MEMS accelerometer) which may result in an output signal (e.g., a signal corresponding to an output from differential sense electrodes of the inertial sensor) that may be processed to determine a signal that is related to (e.g., is proportional to) the motion being sensed (e.g., linear acceleration or angular velocity). This processed output may be provided to the summer block 704.

At block 706, the voltage-induced sensor offset may be determined as described herein. In an exemplary embodiment, a set of shield voltage values may have been tested prior to the sensing of block 702 to generate an offset curve or related values. Based on this information and the operational shield voltage used at block 702, a voltage-induced sensor offset may be calculated and output from block 706. Block 708 may provide scaling for the determined voltage-induced sensor offset so that a value output from block 708 is in the same units and scaling as the output from block 702. The output of block 708 may be provided to summer 704 as a subtraction input to be removed from the output of the measured value from block 702.

Block 710 may access a mechanical sensor offset. In some embodiments the mechanical sensor offset may be a fixed value. In other embodiments, the mechanical sensor offset may be updated, for example, based on the same offset curve used to determine the voltage-induced sensor offset at block 706. If the offset curve is determined during operation, it may be desirable to have a zero or known input of the measured characteristic (e.g., linear acceleration). This mechanical sensor offset may be scaled in the same manner as the outputs from blocks 702 and block 708, and provided to summer 704 to be subtracted from the measured output of block 702. The output of block 704 may therefore correspond to the raw measured output from block 702 at the operational shield voltage, corrected based on the voltage-induced sensor offset and the mechanical sensor offset. The output of summer 704 may then be used to accurately determine the desired sensor output (e.g., linear acceleration or angular velocity).

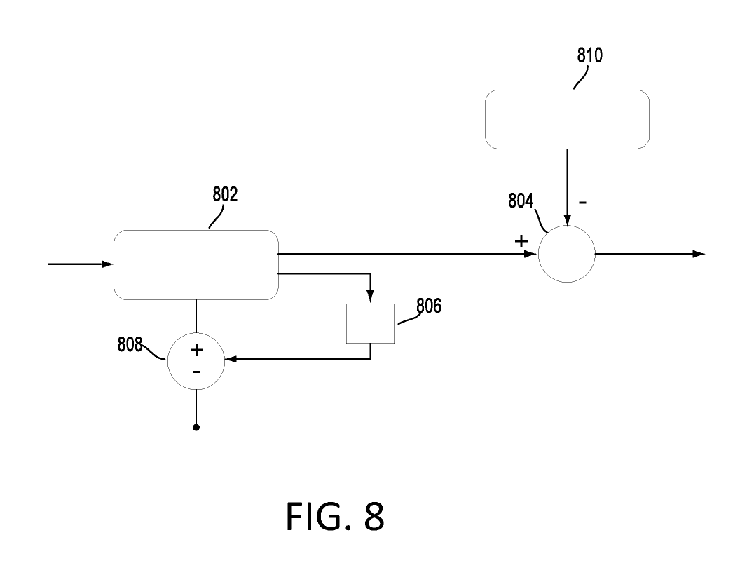

FIG. 8 depicts a block diagram of closed loop correction in accordance with some embodiments of the present disclosure. In an exemplary embodiment of open loop correction, correction for the voltage-induced sensor offset may be performed by performing compensation on measured values from the sensor. It will be understood that additional blocks may be added to or removed from FIG. 8, and that the function or sequence of the blocks may be modified in a variety of suitable manners.

At block 802, sensing may be performed for the sensor (e.g., an inertial sensor such as a MEMS gyroscope or MEMS accelerometer) which may result in an output signal (e.g., a signal corresponding to an output from differential sense electrodes of the inertial sensor) that may be processed to determine a signal that is related to (e.g., is proportional to) the motion being sensed (e.g., linear acceleration or angular velocity). This processed output may be provided to the summer block 704.

At block 806, the voltage-induced sensor offset may be determined as described herein. In an exemplary embodiment, a set of shield voltage values may have been tested prior to the sensing of block 802 to generate an offset curve or related values. Based on this information a minimum offset voltage for the offset curve may be determined and output from block 806. Block 808 may modify the operational shield voltage of the sensor to correspond to the minimum offset voltage, which modifies the operation and sensing of block 802. In this manner, the minimum offset voltage is repeatedly determined, the shield voltage is repeatedly updated to the minimum offset voltage, and the operation value of block 802 is repeatedly modified to eliminate the voltage-induced sensor offset from the signal that is output from block 802.

Block 810 may access a mechanical sensor offset. In some embodiments the mechanical sensor offset may be a fixed value. In other embodiments, the mechanical sensor offset may be updated, for example, based on the same offset curve used to determine the voltage-induced sensor offset at block 806. This mechanical sensor offset may be scaled in the same manner as the outputs from block 802, and provided to summer 704 to be subtracted from the measured output of block 802. The output of block 804 may therefore correspond to the measured output from block 802 with the shield voltage set to the minimum offset voltage, corrected based on the mechanical sensor offset. The output of summer 804 may then be used to accurately determine the desired sensor output (e.g., linear acceleration or angular velocity).

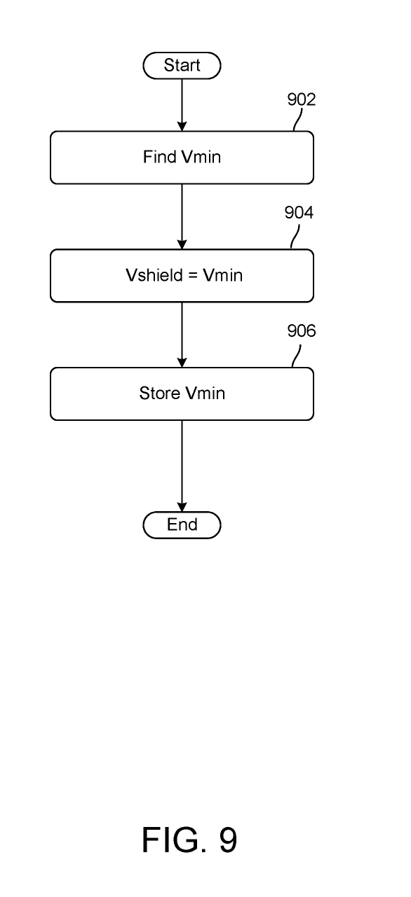

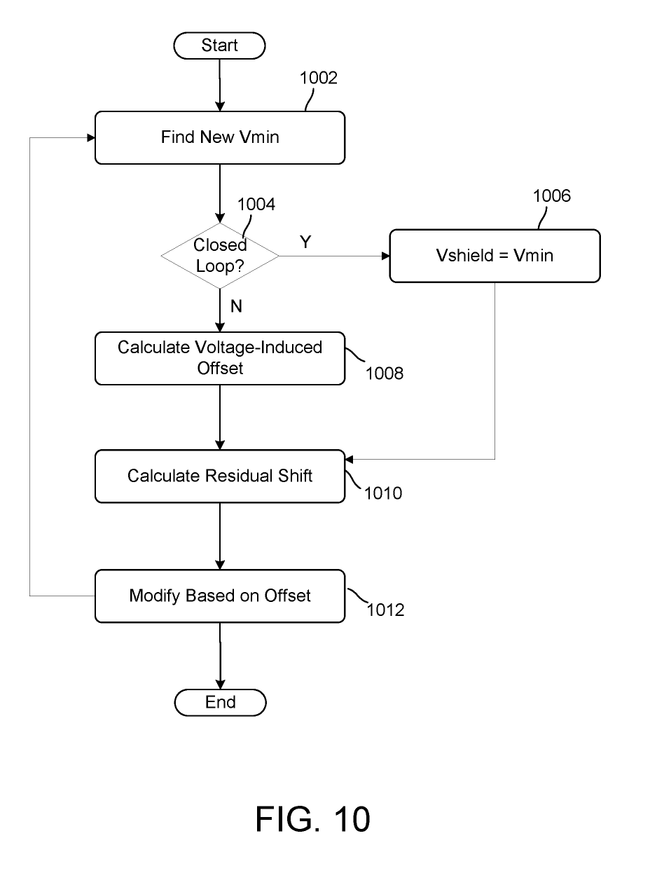

FIGS. 9-10 depict exemplary steps for sensor offset correction in accordance with some embodiments of the present disclosure. Although FIGS. 9-10 are described in the context of the sensors of the present disclosure, it will be understood that the designs, components, configurations, methods, and steps described herein and in FIGS. 9-10 may be applied to any suitable MEMS sensor or components thereof. Although a particular order and flow of steps is depicted in FIGS. 9-10, it will be understood that in some embodiments one or more of the steps may be modified, moved, removed, or added, and that the flow depicted in FIGS. 9-10 may be modified.

FIG. 9 depicts steps for an initial offset correction in accordance with some embodiments of the present disclosure. At step 902, a shield voltage associated with the minimum offset for the offset curve may be identified as described herein, for example, by performing a sweep or iterative searching of voltages for the voltage that yields the minimum offset. Once the voltage is identified, processing may continue to step 904.

At step 904, the voltage of the shield may be modified to match the voltage that corresponds to the minimum offset. In addition, a mechanical sensor offset associated with other factors (e.g., a mechanical offset or offset due to other devices) may be identified. Processing may then continue to step 906, at which the modified shield voltage and other values such as residual voltage may be stored.

FIG. 10 depicts steps for active offset correction in accordance with some embodiments of the present disclosure. In the exemplary embodiment of FIG. 10, the offset shift may be adjusted for during operation of the sensor. At step 1002, a shield voltage associated with the minimum offset for the offset curve may be identified as described herein, for example, by performing a sweep or iterative searching of voltages for the voltage that yields the minimum offset. Once this shield voltage is identified, processing may continue to step 1004.

At step 1004, it may be determined whether correction of any sensor offset will be performed using closed loop methodology (e.g., modifying the shield voltage to reduce the offset) or an open loop methodology (e.g., compensating for the voltage-induced sensor offset by modifying the operation of circuitry and/or scaling factors). If closed loop correction is to be performed, processing may continue to step 1006 at which the shield voltage may be set to the voltage that is associated with the minimum sensor offset. Processing may then continue from step 1006 to step 1010. If open loop correction is to be performed, processing may continue to step 1008 at which the voltage-induced sensor offset is determined and compensation is performed in the measurement circuitry and/or scaling to factor in the known offset. Processing may then continue from step 1008 to step 1010.

At step 1010, the mechanical sensor offset may be determined based on the offset that remains in the sensor even at the minimum offset voltage. If the offset curve is determined during operation, it may be desirable to have a zero or known input of the measured characteristic (e.g., linear acceleration). Compensation may then be performed in the measurement circuitry and/or scaling to remove this mechanical sensor offset from the determination of the measured values at step 1012. Once correction and compensation have been performed for both of the voltage-induced sensor offset and the mechanical sensor offset, the processing of FIG. 10 may end.

The foregoing description includes exemplary embodiments in accordance with the present disclosure. These examples are provided for purposes of illustration only, and not for purposes of limitation. It will be understood that the present disclosure may be implemented in forms different from those explicitly described and depicted herein and that various modifications, optimizations, and variations may be implemented by a person of ordinary skill in the present art, consistent with the following claims.

What is claimed is:

1. A microelectromechanical (MEMS) sensor, comprising:
a proof mass having a plurality of planar surfaces and having a proof mass voltage;
a sense electrode having one or more planar surfaces, wherein at least one of the one or more planar surfaces of the sense electrode is located in parallel to at least one of the planar surfaces of the proof mass, wherein the sense electrode has a sense electrode voltage, and wherein the sense electrode and the proof mass form a sense capacitor;
a shield located on one or more planar surfaces of the microelectromechanical sensor, wherein at least a portion of the shield is located in parallel to at least one of the planar surfaces of the proof mass, wherein the shield has an initial shield voltage, and wherein the shield voltage may be modified; and
processing circuitry coupled to the proof mass, the sense electrode, and the shield, wherein the processing circuitry provides a plurality of test voltages to modify the shield voltage, measures a measured offset value at each of the test voltages, and changes the operation of the MEMS sensor based on at least one of the measured offset values having an improved value compared to an initial offset value associated with the initial shield voltage, and wherein a movement of the proof mass relative to the sense electrode is sensed based on changes in the value of the sense capacitor.

2. The MEMS sensor of claim 1, wherein the change to the operation of the MEMS sensor comprises a change of the shield voltage to an operating shield voltage that corresponds to the measured offset value that is representative of a minimum voltage-induced sensor offset.

3. The MEMS sensor of claim 1, wherein the processing circuitry interpolates a plurality of additional offset values based on the measured offset values, identifies an interpolated offset value that is less than each of the measured offset values, and sets the shield voltage to an operating shield voltage that corresponds to the identified interpolated offset value.

4. The MEMS sensor of claim 3, wherein the processing circuitry interpolates the plurality of additional offset values based on a predetermined pattern.

5. The MEMS sensor of claim 4, wherein the predetermined pattern is a parabolic pattern.

6. The MEMS sensor of claim 5, wherein the identified interpolated offset value corresponds to a point at which the derivative of the parabolic pattern is substantially zero.

7. The MEMS sensor of claim 1, wherein the change to the operation of the MEMS sensor comprises a change of the shield voltage to an operating shield voltage that corresponds to an operating offset value that reduces a voltage-induced sensor offset associated with the initial offset value, wherein the change of the shield voltage is based on the measured offset values.

8. The MEMS sensor of claim 7, wherein the processing circuitry measures one or more additional offset values associated with the operating shield voltage after the operating shield voltage is applied to the shield, and determines a revised operating offset value based on a difference between the one or more additional offset values and one or more of the measured offset values.

9. The MEMS sensor of claim 8, wherein the movement of the proof mass relative to the sense electrode is sensed based on changes in the value of the sense capacitor and the revised operating offset value.

10. The MEMS sensor of claim 8, wherein the operating shield voltage is changed to a revised operating shield voltage based on the revised operating offset value.

11. The MEMS sensor of claim 1, wherein the movement of the proof mass relative to the sense electrode is sensed based on the initial offset value and changes in the value of the sense capacitor.

12. The MEMS sensor of claim 1, wherein the processing circuitry measures one or more additional offset values associated with the initial shield voltage after the initial shield voltage is applied to the shield, determines a revised initial offset value based on a difference between the one or more additional offset values and one or more of the measured offset values, and wherein the movement of the proof mass relative to the sense electrode is sensed based on changes in the value of the sense capacitor and the revised initial offset value.

13. The MEMS sensor of claim 1, wherein the processing circuitry determines a mechanical sensor offset value based on the initial offset value.

14. The MEMS sensor of claim 13, wherein the processing circuitry modifies a measured value for the MEMS sensor based on the mechanical sensor offset value.

15. The MEMS sensor of claim 13, wherein the processing circuitry further modifies one or more voltages of one or more additional components of the MEMS sensor to reduce the mechanical sensor offset value.

16. The MEMS sensor of claim 1, wherein at least a portion of the shield is located on a substrate that is parallel to the largest surface by area of the planar surfaces of the proof mass.

17. The MEMS sensor of claim 16, wherein the sense electrode is located on the substrate.

18. The MEMS sensor of claim 1, wherein the proof mass is located within a MEMS device plane, and wherein at least a portion of the sense electrode is located within the MEMS device plane.

19. A method for operating a microelectromechanical (MEMS) sensor, comprising:
providing, to a shield of the MEMS sensor, a plurality of test voltages;
determining, based on measured movement of a proof mass of the MEMS sensor, an offset value associated with each of the plurality of test voltages;
identifying, based on the measured movements of the proof mass, a voltage-induced sensor offset associated with an operating voltage of the shield;
measuring, based on a capacitor formed by the proof mass and a sense electrode of the MEMS sensor, a measured value for the sensor; and
correcting the measured value based on at least the voltage-induced sensor offset.

20. A microelectromechanical (MEMS) sensor, comprising:
a proof mass having a plurality of planar surfaces and having a proof mass voltage;
a sense electrode having one or more planar surfaces, wherein at least one of the one or more planar surfaces of the sense electrode is located in parallel to at least one of the planar surfaces of the proof mass, wherein the sense electrode has a sense electrode voltage, and wherein the sense electrode and the proof mass form a sense capacitor;
a shield located on one or more planar surfaces of the microelectromechanical sensor, wherein at least a portion of the shield is located in parallel to at least one of the planar surfaces of the proof mass; and
processing circuitry coupled to the proof mass, the sense electrode, and the shield, wherein the processing circuitry provides a plurality of test voltages to one or more of the proof mass or the shield, measures an offset value at each of the test voltages, determines a voltage-induced sensor offset based on one or more of the measured offset values, and modifies a sensed signal from the sense capacitor based on the voltage-induced sensor offset.
